(19) United States
(12) Patent Application Publication
(10) Pub. No.: US 2018/0007803 A1
(43) Pub. Date: Jan. 4, 2018

(54) CONFIGURABLE DEVICE COMPRISING A SCREEN AND SUITABLE TO SUPPORT A COMPUTER

(71) Applicants: SCHIPANI Giuseppe, CERNUSCO LOMBARDONE (Lecco) (IT); Fiammetta RAVOT, CERNUSCO LOMBARDONE (Lecco) (IT)

(72) Inventors: SCHIPANI Giuseppe, CERNUSCO LOMBARDONE (Lecco) (IT); Fiammetta RAVOT, CERNUSCO LOMBARDONE (Lecco) (IT)

(21) Appl. No.: 15/542,841

(22) PCT Filed: Jan. 13, 2016
(86) PCT No.: PCT/IB2016/050129

§ 371 Date: Jul. 11, 2017

(30) Foreign Application Priority Data
Jan. 13, 2015 (IT) MI2015A000018

(51) Int. Cl. H05K 5/02; G06F 1/16; F16M 11/18; F16M 11/10; F16M 11/38; G06F 1/18; F16M 11/42

(52) U.S. Cl. CPC H05K 5/0234; G06F 1/18; G06F 1/1601; F16M 11/42; F16M 11/10; F16M 11/38; F16M 11/18; F16M 2200/08

(57) ABSTRACT

Provided is a configurable device including a screen and configured to support a computer, the configurable device further including a support frame having consecutive operating portions and joints defining axes of rotation between the operating portions, reciprocal positioning means of the operating portions, the operating portions further including a base unit, an upper unit connected to the screen, and at least one intermediate unit connected between the base unit and the upper unit, the configurable device lastly including actuation members configured to automatically control the positioning means.

The present invention relates to a configurable device comprising a screen and suitable to support a computer, of the type specified in the preamble of the first claim.

As known, on the market there are various articulated and jointed tables suitable to support a monitor or a computer, in order to allow a user to operate as comfortably as possible and with the upper supporting surface at the correct height.

The height varies in particular if operating is envisaged while sitting, as in offices, or standing, such as at a reception desk or reception point of a trade fair or exhibition.

A similar device is for example described in the patent application US-A-2006/0054751, which shows a pantograph support for a computer, suitable to be adjusted in height from the ground. However, this is limited to adjusting the height from the ground in a restricted manner, like any lifting device.

Another device is described in the patent application DE-A-3437300. However this is an articulated arm for attaching to a wall and comprises mutually interconnected portions which allow only very limited particular movements.

There are also, in the advertising sector and at trade shows and exhibitions, special, substantially column-like supports, commonly called “totems”, which display in a raised position, chosen according to the environment and specific needs, advertising signs and various directions, possibly presented on a screen.

For example it is typical to have a totem with a screen in a substantially vertical position and at eye height of passers-by.

At trade fairs and exhibitions the screens or advertising elements or directions may also be placed—using appropriate supports—essentially at ground level, for example, to enhance and document a display area or a special step.

One drawback of this situation is that work tables and totems are very different structures from each other and are not able, except marginally and unsatisfactorily, to meet the different needs of the work table and the display totem.

Also, when said work tables are adjustable in height, relatively laborious to adjustment operations are involved, such as not to allow the immediate achievement of optimal positions, or perfectly aligned positions when several tables close by are used together.

The transport is then complex both for tables and for totems, which in many cases consist of monolithic columns extensive in height and in any case always cumbersome.

In practice, operators setting up halls or stands at exhibitions or fairs face a demanding job both in terms of assembly and dismantling with results which are not always satisfactory from various aspects.

Among others, tables and totems of varying height in their diversity also determine an uneven and aesthetically haphazard appearance of the individual halls or point of sales.

### SUMMARY OF THE INVENTION

In this situation the technical task according to the present invention is to devise a configurable device comprising a screen and suitable to support a computer, able to substantially overcome the drawbacks mentioned.

Another important object of the invention is to devise a device which can support a monitor or a computer in many positions, choosing both the height and the most suitable inclination.

A further object of the invention is to devise a device in which the optimal positioning of the display element can be achieved immediately and accurately.

Another important object is to devise a device which is easy to transport even by hand, and compact.

A further, no less important object of the invention is to provide a solid device, aesthetically attractive and customizable for advertising or aesthetic purposes.

The technical purpose and specified aims are achieved by a configurable device for the support and positioning of a display element, in particular a monitor, as claimed in the appended Claim 1.

Preferred embodiments are evident from the dependent claims.

The characteristics and advantages of the invention are clearly evident from the following detailed description of preferred embodiments thereof, with reference to the accompanying drawings, in which:

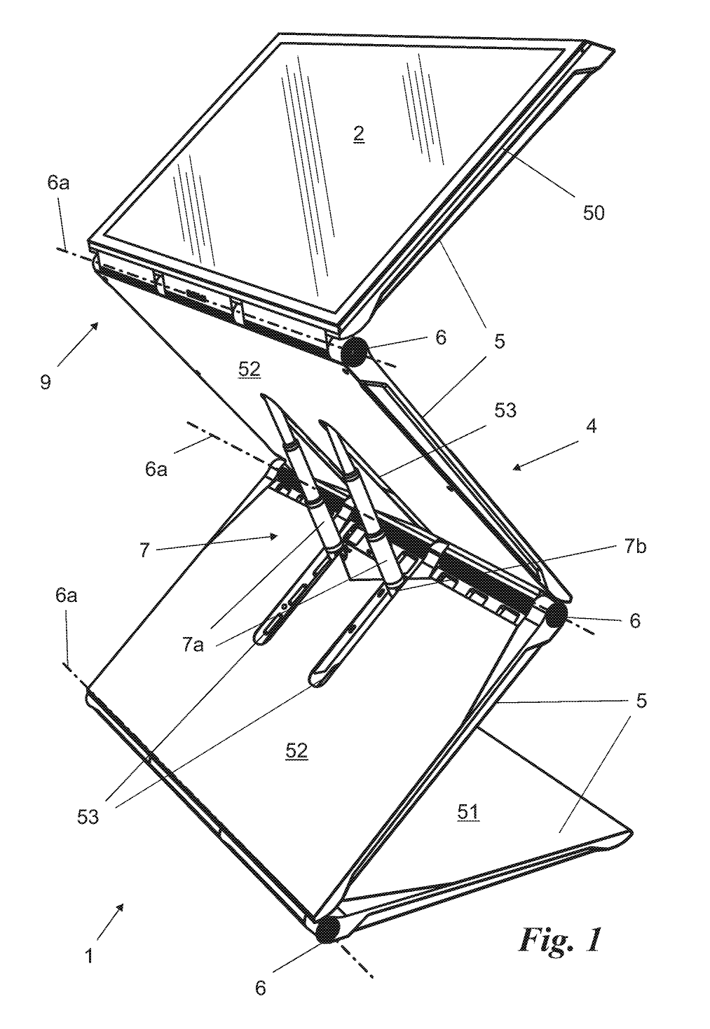

FIG. 1 shows an axonometric view of the front portion of the configurable device for supporting and positioning a display element according to the invention;

FIG. 2 shows an axonometric view of the rear portion of the configurable device according to the invention;

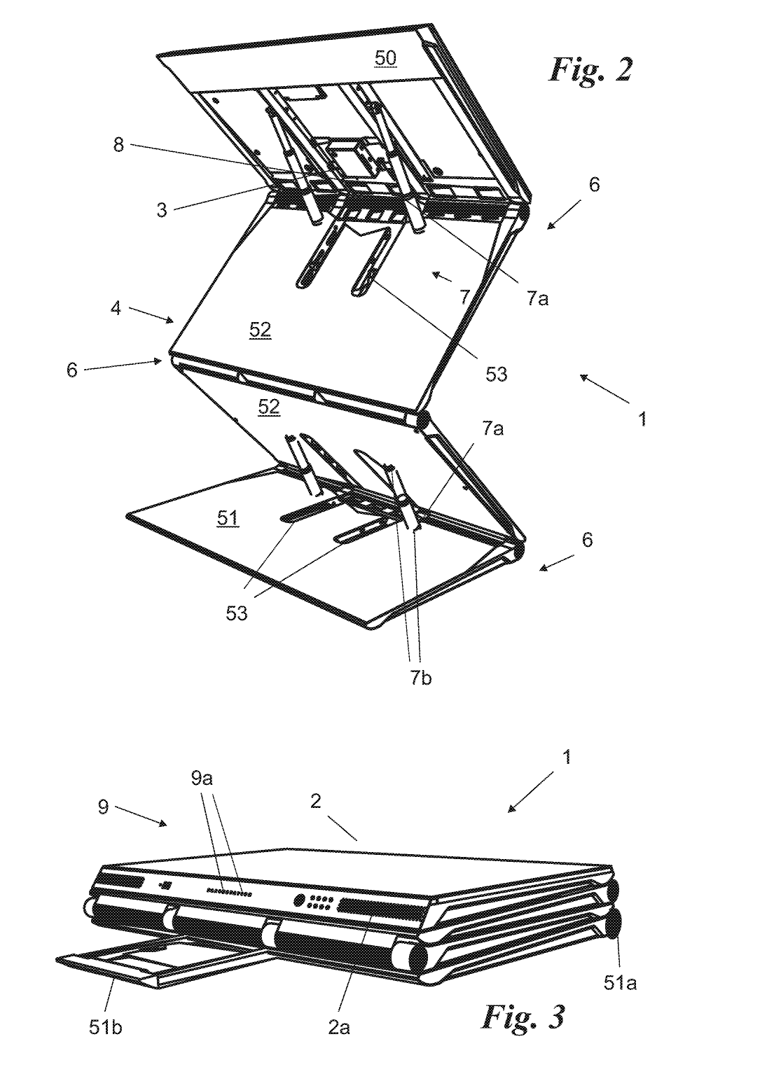

FIG. 3 shows a compact configuration of the configurable device according to the invention;

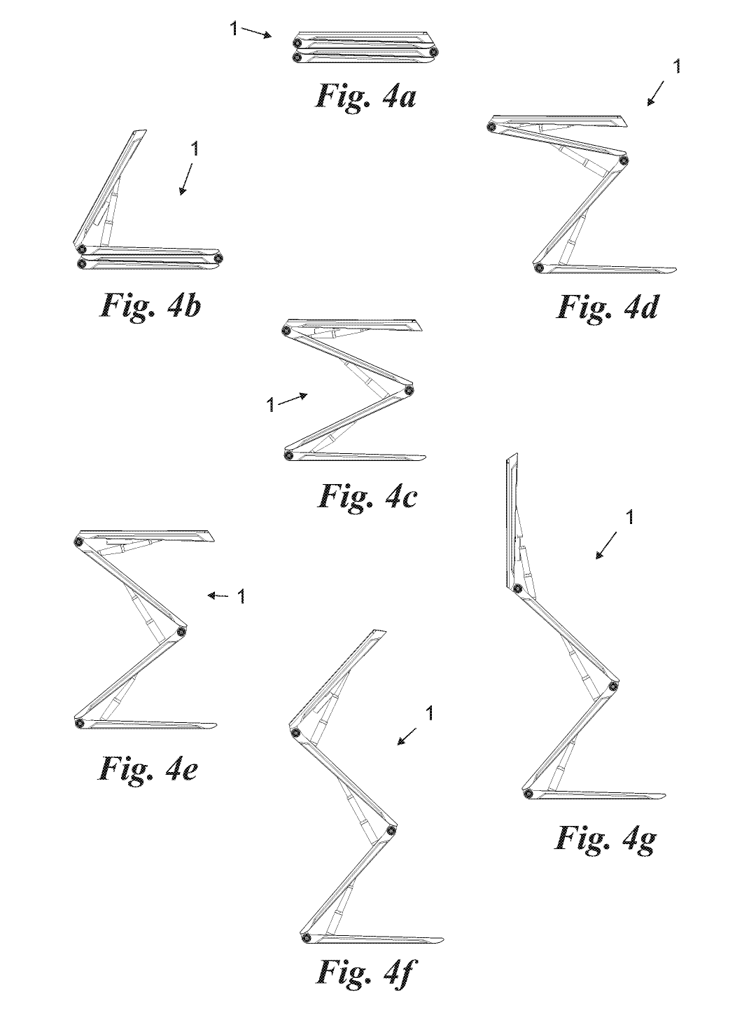

FIG. 4a is a side view of the device in a first configuration;

FIG. 4b is a side view of the device in a second configuration;

FIG. 4c is a side view of the device in a third configuration;

FIG. 4d is a side view of the device in a fourth configuration;

FIG. 4e is a side view of the device in a fifth configuration;

FIG. 4f is a side view of the device in a sixth configuration;

FIG. 4g is a side view of the device in a seventh configuration;

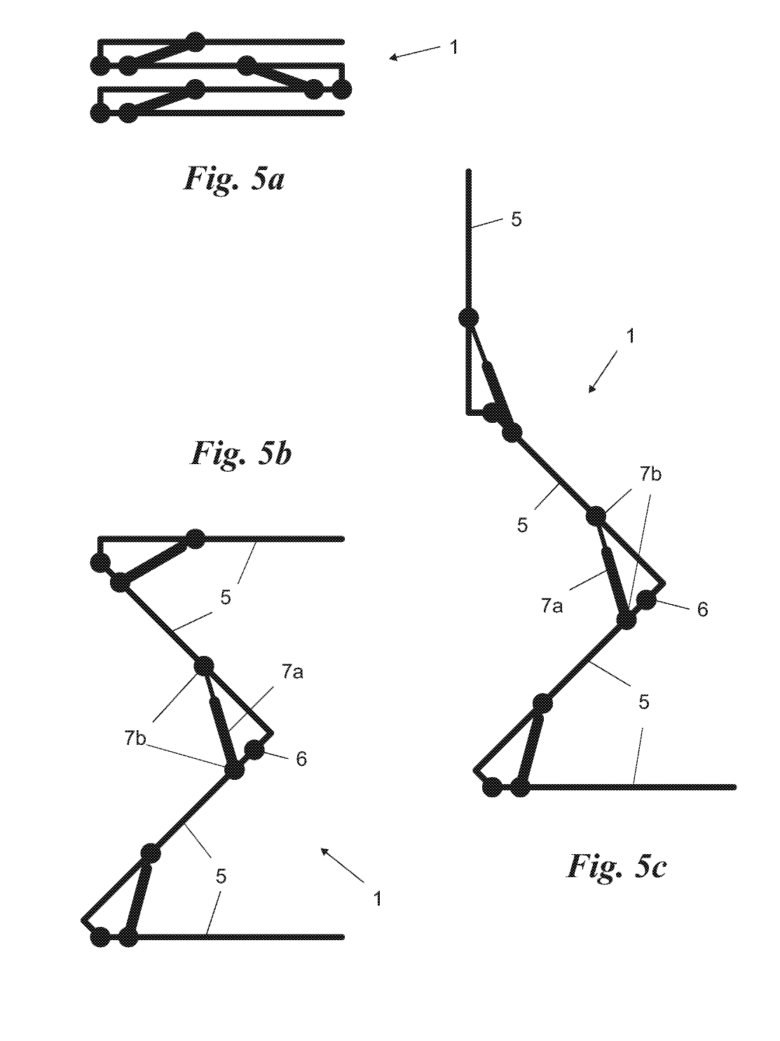

FIG. 5a is an operating diagram of the device in a first configuration;

FIG. 5b is an operating diagram of the device in a second configuration;

FIG. 5c is an operating diagram of the device in a third configuration.

With reference to the Drawings, reference numeral 1 globally denotes the configurable device according to the invention.

It comprises, in brief, a screen 2 and it supports, and preferably comprises a computer 3, and lastly a support frame 4, available in various configurations, as described below.

More specifically, the screen 2 preferably has a diagonal dimension between 20 inches and 60 inches, more preferably between 24 inches and 47 inches (one inch=2.54 cm) and a ratio between the sides, of between 1.3 and 1.8 and preferably equal to 16/9. It is also preferably a touchscreen.

The computer 3 is preferably of the compact type and of the type substantially commonly available on the market, such as a PC or the like. It is connected to the screen 2, and typical computer external devices such as keyboard, mouse, printers and the like can be connected to it. The keyboard, however, is not essential since the screen 2 is preferably a touchscreen.

The support frame 4 comprises consecutive operating portions 5 and joints 6 defining axes of rotation 6a between said operating portions, suitable to permit, in a mutually independent manner, the reciprocal mobility of said operating portions 5 and of said screen 2. The term independently of each other is taken to mean that the degrees of freedom of the joints 6 of the individual portions are not mutually constrained, as is clear from the appended drawings 4a-4f.

Said operating portions 5 are preferably substantially flat elements, while the joints 6 define rotation axes parallel and lying along the sides of the operating portions 5. More preferably, the operating portions 5 are substantially rectangles with rotation axes lying along the sides, preferably along the long sides. The rectangles also preferably have similar proportions to the proportions of the sides of the screen 2, previously described. Substantially, the support frame 4 can extend so as to constitute a single rectangle or fold back on itself in a packet.

The operating portions 5 are also preferably made of metal, suitably aluminium or aluminium alloy. Each individual portion is furthermore structurally composed of a plurality of beams, preferably I-beams, which extend in the plane composed of the portion 5 and the vertical direction of which, i.e. the main direction of extension of the normal cross-section, lies in the plane perpendicular to the plane of the portion 5. Said beams preferably delineate at least the profile of the individual portion 5 and/or inner parts of said portion 5. The operating portions 5 are furthermore covered by aesthetic elements such as sheet metal or the like.

The operating portions 5 comprise a base unit 51, which constitutes one of said operating portions 5 and which is suitable to permit the support on the ground of the configurable device 1.

The operating portions 5 also comprise an upper unit 50, which constitutes another operating portion 5 and which is connected to the screen 2. Preferably, the screen 2 is integrally constrained to said upper unit 50 and lies substantially on the same plane and inside the metal structure of the upper unit 50, as illustrated in FIG. 1. The body or case of the computer 3 is also preferably rigidly constrained to the upper unit (FIG. 2).

The operating portions 5 then comprise at least one intermediate unit 52 connected between the base unit 51 and the upper unit 50. Preferably there are two intermediate units 52: a first intermediate unit, connected to the upper unit 50, and a second intermediate unit, connected to the base unit 51. Said two intermediate units 52 are also mutually connected.

The joints 6 define axes of rotation 6a which coincide with the long sides of the rectangles of the portions 5 and preferably comprise pins the size of one side of the operating portions 5. In addition, the side of the base unit 51, connected to the adjacent intermediate unit 52 preferably comprises castors 51a resting on the ground, preferably constrained to the same pin which constitutes the joint 6. Said castors 51a can also preferably be quickly assembled. In addition, said base unit 51 preferably comprises an extractable handle element 51b on the opposite side to the castors (FIG. 3).

The configurable device 1 further comprises reciprocal positioning means 7 of the operating portions 5, suitable to adjust, independently of each other, the position of said operating portions 5 around degrees of freedom defined by the joints 6. The term independently of each other is taken to mean that the movements and positioning of the individual operating portions 5 and the screen 2 are not mutually constrained, and that it is possible to move one portion around a degree of freedom 6a, without moving the others.

These preferably comprise linear actuators 7a, preferably telescopic, and preferably of the electromechanical type, more particularly of the worm screw type, placed between consecutive operating portions 5 and transversely to the rotation axes 6a. Alternatively they could comprise rotational motors or otherwise.

Said linear actuators 7a are preferably connected to the two adjacent operating portions 5 by means of hinges 7b, so as to constitute, together with the hinge composed of the joint 6 which joins the two said operating portions 5, a three-hinge arch, as shown schematically in FIGS. 5a-5c. The said three-hinged arch has a degree of freedom consisting of the adjustability of the length of the telescopic actuator 7a.

The linear actuators 7a preferably may distance adjacent operating portions 5 by angles close to a flat angle or may close them in a packet (FIGS. 5c and 4a). In particular between the upper unit 50 and a consecutive intermediate unit 52 said to joints 6 and said positioning means 7 are suitable to define an angle greater than a right angle (FIGS. 5c and 4g).

The positioning means 7 further comprise, appropriately, detection means of the absolute position at least of the screen 2 and preferably also the absolute position of the operating portions 5. Such detection means are preferably accelerometers and/or gyroscopes.

Furthermore, in order to allow the packed closure of the configurable device 1, seats 53 are present along the operating portions, suitable to house the linear actuators 7a in the position of minimum angular opening or closing in a package.

The configurable device 1 further comprises actuation members 8 suitable to automatically control the positioning means 7 and preferably of the electric or electronic type and more preferably belonging to the computer 3. The term automatically means, of course, that the actuation is not manual but electrical, electromechanical or magnetic.

The actuation members 8 are preferably suitable to impose on the positioning means 7, a plurality of specific and preselected working positions of the support frame 4. This is therefore a finite number, preferably 7 or 8, of positions that the support frame 4 can assume. Such positions are described further below.

In particular the working positions correspond to specific extensions of the linear actuators 7a.

The actuation members 8 further comprise a control panel 9 located on the upper unit 50 and comprising control buttons 9a, appropriately connected to the computer 3, each of which related to a specific working position of the frame. In a different preferred embodiment the command for the specific working position of the frame is a vocal command. In this case the control panel 9 can be reduced to the minimum necessary.

The device 1 lastly comprises loudspeakers 2a, preferably placed on the upper unit 50.

The functioning and the use of the configurable device 1 according to the invention, described above in a structural sense, is as follows.

The configurable device 1 can be placed in one of said working positions, as illustrated in FIG. 4a.

In particular, said working positions comprise a transport position, in which said operating portions 5 are clamped together in a pack, illustrated in FIG. 4a. In this position, the device is simple to transport, thanks to the castors 51a and to the pull-out handle element 51b.

Said working positions comprise then, at least one, and preferably two or three, planar positions where the base unit 51 and upper unit 50 are substantially parallel and form tables of varying height, as illustrated in FIGS. 4c, 4d and 4e. In this position, the computer is simple to use thanks to the touchscreen display.

Said working positions also comprise at least one, and preferably two, totem positions, in which the upper unit 50 forms an angle less than half a right angle with the vertical direction (FIGS. 4f and 4g). In particular, in a position in which the screen 2 is substantially vertical (FIG. 4g), and in a position in which the screen is approximately 45° (FIG. 4f). In these positions, the configurable device 1 can be used as a totem for example at trade fairs and exhibitions.

Lastly, the working positions also comprise at least one position on the ground (FIG. 4b), in which said upper unit 50 forms an angle less than half the right angle with the vertical direction and the remaining operating portions 5 are clamped together in a pack. In this position the device 1 is used substantially in the same way as a traditional computer.

Said seven positions preferably each have and are controlled by a single command button 9a. A last command button 9a may be left free for by the end user. Alternatively said positions are associated with voice commands.

To achieve positioning in the positions described these are first of all selected by the user using the actuation members 8.

The latter, thanks to the described computer, activate the positioning means 7 which move the joints 6 and place the screen 2 and the operating units 5 in the position selected. Following the positioning, the detection means of the absolute position check the positions. In particular, said detection means of the absolute position check the absolute position of the screen 2, for example its perpendicularity, or angle of inclination, with respect to the gravity gradient. If the location is not correct, the positioning means 7 perform a new positioning until the correct absolute position is located, for example with respect to the gravity gradient, regardless of the slope of the ground.

The invention achieves the proposed objectives and permits important advantages.

In fact, the configurable device 1 is simply and quickly available at the most suitable heights and inclinations. In particular, specific and particular positions can be achieved, such as those illustrated in FIGS. 4b, 4d, 4f and 4g, which would not be obtainable with mutually constrained operating portions 5 such as a pantograph or similar solutions. The detection means of the absolute position also make it possible to always maintain the correct positioning and not multiply any small positioning errors of the actuators and, especially, to maintain the correct position regardless of the inclination of the ground.

Furthermore, the device 1 enables an optimal positioning of the screen 2 reached with immediacy, simplicity and precision, since it is completely automated.

Another advantage is given by the fact that the device is easily transportable even manually, in particular in the transport position.

Lastly, it is solid, compact and customizable for advertising or aesthetic purposes; it is in fact very proportionate and aesthetically attractive.

Variations may be made to the invention without departing from the scope of the inventive concept defined in the independent claims and by their technical equivalents.

All details may be replaced with equivalent elements and the materials, shapes and dimensions may be any within the scope of protection defined by the claims.

1. A configurable device comprising a screen and configured to support a computer, said configurable device further comprising:
a support frame having consecutive operating portions and joints defining axes of rotation between said operating portions;
and reciprocal positioning means of said operating portions, wherein said joints and said positioning means are configured to move, in a mutually independent manner, said operating portions and said screen,
said operating portions comprise a base unit, an upper unit connected to said screen, and at least one intermediate unit connected between said base unit and said upper unit,
and comprises actuation members configured to automatically control said positioning means.

2. The device according to claim 1, wherein said positioning means comprise detection means of the absolute position at least of said screen.

3. The device according to claim 1, wherein said positioning means comprise detection means of the absolute position at least of said operating portions.

4. The device according to claim 1, wherein said positioning means comprise linear actuators positioned between said consecutive operating portions, transversely to said axes of rotation.

5. The device according to claim 4, wherein actuation members are provided configured to impose on said linear actuators of a plurality of preselected expansions corresponding to a plurality of specific working positions of said support frame.

6. The device according to claim 5, wherein said specific working positions are configured to configure at least: a transport position in which the said operating portions are clamped together in a package, at least a flat position where said base unit and upper unit are substantially parallel and form tables of varying height, and a plurality of totem positions in which said upper unit forms an angle smaller than half a right angle with the vertical direction.

7. The device according to claim 6, wherein said specific working positions are configured to configure at least one ground position in which said upper unit forms an angle less than half a right angle with the vertical direction and the remaining operating portions are clamped together in a package.

8. The device according to claim 1, in which two of said intermediate units are present.

9. The device according to claim 1, wherein between said upper unit and a consecutive intermediate unit said joints and said positioning means are suitable to define an angle greater than a right angle.

10. The device according to claim 1, wherein said actuation members comprise a control panel positioned in correspondence with said upper unit comprising control buttons, each of said buttons being correlated to a specific working position of said frame.

11. The device according to claim 1, wherein said screen is of the touch screen type and integral with said upper unit.

12. The device according to claim 1, wherein said base unit has wheels resting on the ground, and an extractable handle element.
